(19) United States
(12) Patent Application Publication
(10) Pub. No.: US 2025/0229596 A1
(43) Pub. Date: Jul. 17, 2025

(54) INTAKE DUCT

(71) Applicant: TOYOTA JIDOSHA KABUSHIKI KAISHA, Toyota-shi Aichi-ken (JP)

(72) Inventor: Yuki UCHITA, Seto-shi Aichi-ken (JP)

(73) Assignee: TOYOTA JIDOSHA KABUSHIKI KAISHA, Toyota-shi Aichi-ken (JP)

(21) Appl. No.: 19/010,308

(22) Filed: Jan. 6, 2025

(30) Foreign Application Priority Data
Jan. 16, 2024 (JP) 2024-004565
Sep. 3, 2024 (JP) 2024-151696

(51) Int. Cl. B60H 1/00

(52) U.S. Cl. CPC B60H 1/00564; B60H 1/00271; B60H 2001/003

(57) ABSTRACT

An intake duct includes: an air inlet; a reservoir pocket for storing liquid flowing from the air inlet; and a discharge port for discharging liquid from the reservoir pocket. Further, the reservoir pocket is provided just behind the air inlet, and a bottom surface of the reservoir pocket is shaped to be inclined with respect to a horizontal direction so as to guide the liquid to the discharge port.

### CROSS-REFERENCE TO RELATED APPLICATION(S)

The present application claims priority to and incorporates by reference the entire contents of Japanese Patent Application No. 2024-151696 filed in Japan on Sep. 3, 2024, which claims priority to and incorporates by reference the entire contents of Japanese Patent Application No. 2024-004565 filed in Japan on Jan. 16, 2024.

The present disclosure relates to intake ducts.

The cooling device disclosed in Japanese Laid-open Patent Publication No. 2014-129039 is disposed in the lower part of the vehicle, and includes a duct in which a liquid reservoir in which the liquid flowing in from the inlet is accumulated is provided.

### SUMMARY

There is a need for providing an intake duct capable of suppressing the flow of liquid into the back of the duct.

According to an embodiment, an intake duct includes: an air inlet; a reservoir pocket for storing liquid flowing from the air inlet; and a discharge port for discharging liquid from the reservoir pocket. Further, the reservoir pocket is provided just behind the air inlet, and a bottom surface of the reservoir pocket is shaped to be inclined with respect to a horizontal direction so as to guide the liquid to the discharge port.

### BRIEF DESCRIPTION OF THE DRAWINGS

FIG. 1 is a side perspective view schematically illustrating an example of a vehicle mounted state of the cooling device provided with the air intake duct according to a first embodiment;

FIG. 2 is a perspective view of a chiller and DCDC converters on a floor panel;

FIG. 3 is a side view of the air inlet duct according to the first embodiment as viewed from an air inlet side.

FIG. 4 is a perspective view of the air inlet duct according to the first embodiment from the air inlet side.

FIG. 5 is a view of a liquid reservoir pocket of the air intake duct according to the first embodiment from below;

FIG. 6 is an explanatory view of an example of a method of setting the diameter of the discharge port provided in the liquid reservoir pocket;

FIG. 7 is a side view of the air intake duct according to a second embodiment as viewed from the air inlet side;

FIG. 8 is a view of the air intake duct according to the second embodiment from below; and

FIG. 9 is a diagram illustrating a state in which the leg portion of the air intake duct according to the second embodiment is applied to a floor silencer.

### DETAILED DESCRIPTION

In the duct comprising the cooling device disclosed in Japanese Laid-open Patent Publication No. 2014-129039, since the liquid reservoir is provided in the middle of the duct, the liquid easily flows into the duct depth.

### First Embodiment

Hereinafter, a first embodiment of an intake duct according to the present disclosure will be described. Note that the present disclosure is not limited to the embodiment.

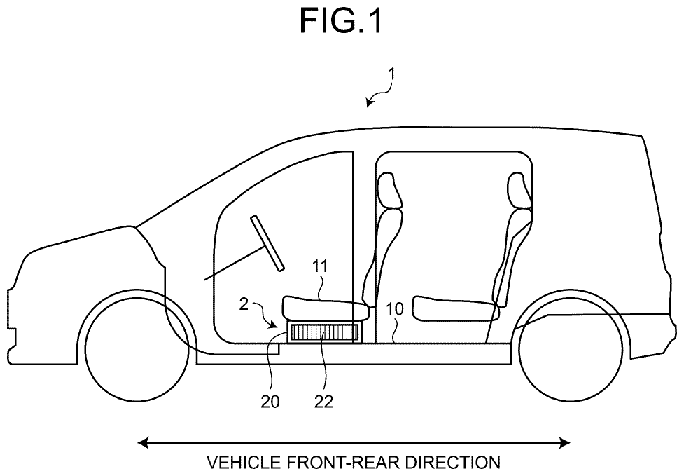

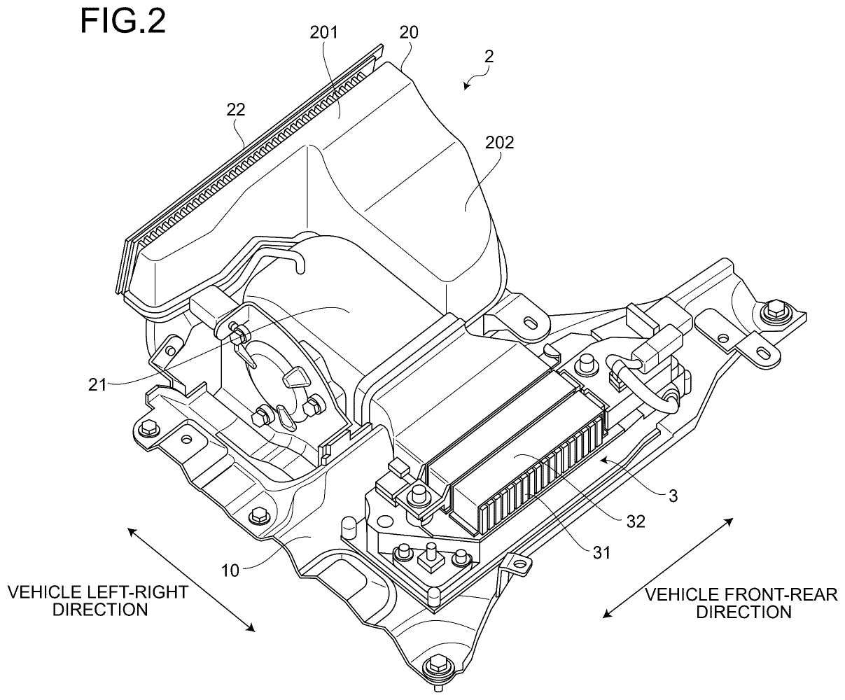

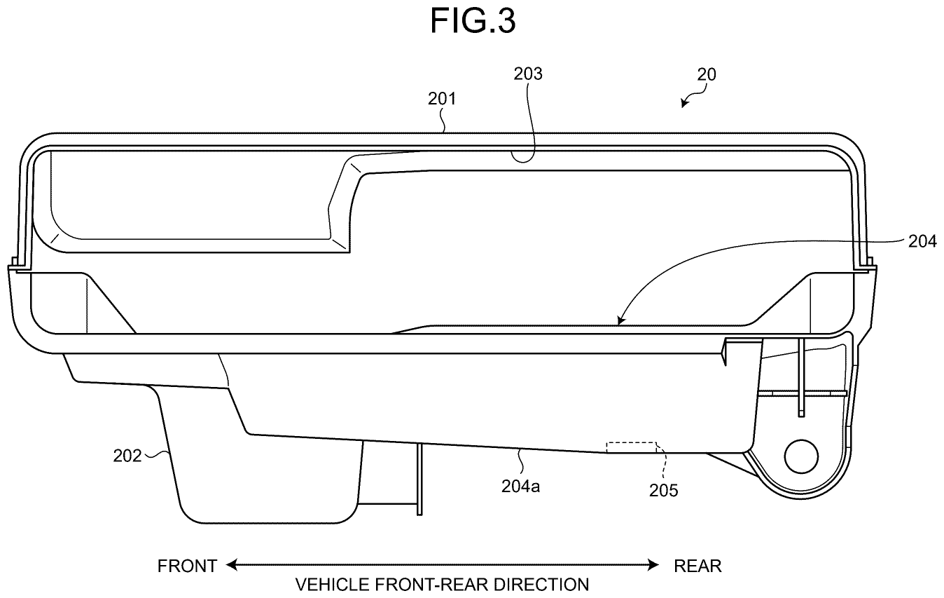

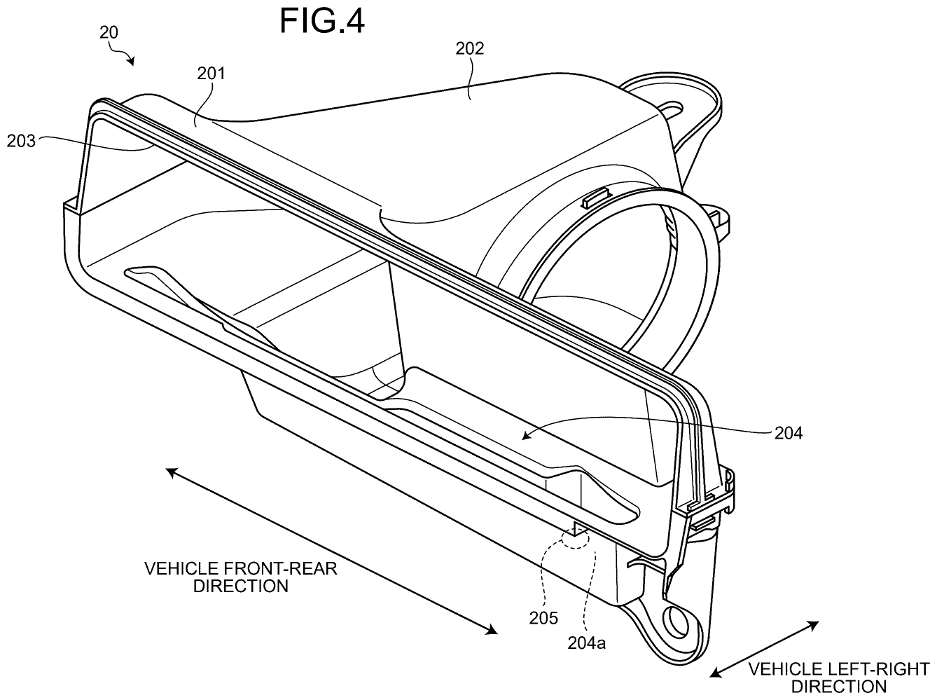

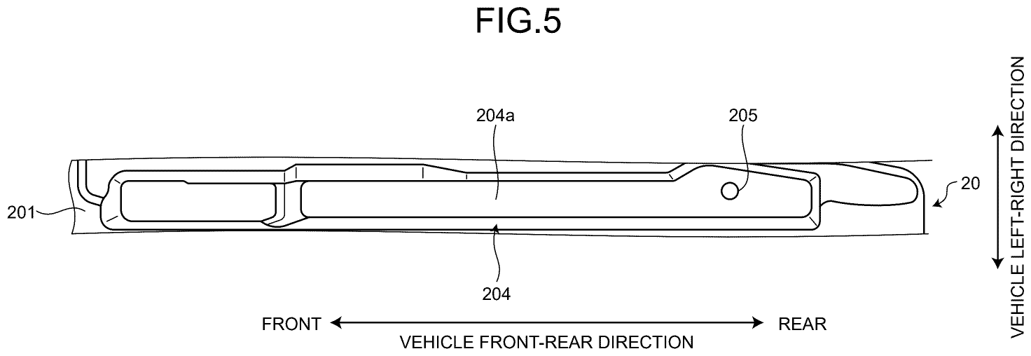

FIG. 1 is a side perspective view schematically illustrating an example of a vehicle mounted state of the cooling device 2 provided with the air intake duct 20 according to the first embodiment. FIG. 2 is a perspective view illustrating a cooling device 2 and DCDC converters 3 provided on the floor panel 10. FIG. 3 is a side view of the air inlet duct 20 according to the first embodiment as viewed from the air inlet 203 side. FIG. 4 is a perspective view of the air inlet duct 20 according to the first embodiment from the air inlet 203 side. FIG. 5 is a view of the liquid reservoir pocket 204 of the air intake duct 20 according to the first embodiment from below.

The cooling device 2 according to the first embodiment is mounted on the vehicle 1 to cool DCDC converters 3. The cooling device 2 is provided on the floor panel 10 of the vehicle 1 together with the DCDC converters 3. In the example illustrated in FIG. 1, the cooling device 2 is provided below the front seat 11 of the front seat. In the exemplary embodiment illustrated in FIG. 1, the DCDC converters 3 may be arranged side by side on the vehicle inside than the cooling device 2 in the vehicle lateral direction with respect to the cooling device 2.

The cooling device 2 includes an air intake duct 20, a cooling blower 21, and an air intake filter 22. The cooling blower 21 is an electrically powered fan, which forms an air flow such that air drawn in through intake filters 22 from intake ports 203 (see FIG. 3) of intake ducts 20 is directed through intake ducts 20 to heat sinks 31 of DCDC converters 3. The heat sink 31 is covered with an upper portion or the like by a cover member 32 connected to the downstream end of the cooling blower 21. Then, the heat radiation from the heat sink 31 is promoted by the air flowing between the heat sink 31 and the cover member 32, so that the DCDC converter 3 is cooled.

The air intake duct 20, as illustrated in FIG. 2, has an air inlet-side duct portion 201, and a blower-side duct portion 202, and forms a pipe line of closed cross-section. The inlet-side duct portion 201 and the blower-side duct portion 202 is formed of resin. The blower-side duct portion 202 has one end connected to the air inlet-side duct portion 201, and the other end is connected to the cooling blower 21. Incidentally, the air inlet-side duct portion 201 and the blower-side duct portion 202 is formed integrally. Further, the air inlet-side duct portion 201 and the blower-side duct portion 202 is formed by dividing into two at the top and bottom, it is assembled and integrated.

On the air inlet side duct portion 201, the air inlet 203 is provided. The air intake port 203 communicates the space inside the air intake duct 20 to the outside of the air intake duct 20. Further, on the air inlet 203, the air inlet filter 22 is attached.

The air inlet 203 is an outer in the vehicle width direction, is provided so as to open toward the door side adjacent to the seat 11 of the front seat located above the cooling device 2. That is, the air inlet 203 is formed on the side surface of the air inlet-side duct portion 201 in the vehicle width direction. Therefore, when a container in which a liquid such as a PET bottle enters the gap between the door and the sheet 11 falls in an open state, the liquid in the container flows out and flows into the intake duct 20 from the intake port 203 there is a case.

Therefore, in the air inlet duct 20 according to the first embodiment, in the lower portion of the air inlet-side duct portion 201, the housing portion of the groove shape extending over the width direction of the air inlet 203 (vehicle front-rear direction) (liquid reservoir) reservoir pocket 204 is provided. The liquid accumulating pocket 204 is formed immediately after the intake port 203 and has a function of temporarily accumulating the liquid flowing into the intake duct 20 from the intake port 203. The liquid reservoir pocket 204 is formed in a part of the width direction of the inlet-side duct portion 201.

The air inlet-side duct portion 201, a discharge port 205 for discharging the liquid accumulated in the liquid reservoir pocket 204 to the outside of the air inlet duct 20 is provided. The discharge port 205 is a round hole, and is provided at the lowermost portion on the bottom 204a of the reservoir pocket 204. The shape of the discharge port 205 is not limited to a round hole, but may be a shape in which an opening capable of discharging a liquid such as a rectangular shape is formed. Further, for the discharge port 205, as long as the opening area is the same, it is not necessary to have the shape in which only one opening is formed, and it is also possible to have a shape in which a plurality of openings is formed. The bottom 204a of the reservoir 204 is shaped to tilt horizontally to direct fluid to the outlet 205.

Thus, in the intake duct 20 according to the first embodiment, the liquid flowing from the intake port 203 into the intake duct 20, together with temporarily accumulated in the liquid reservoir pocket 204 provided immediately after the intake port 203, it is possible to discharge from the discharge port 205 to the outside of the intake duct 20. Further, since the discharging port 205 is provided at the lowermost portion of the bottom 204a of the liquid accumulating pocket 204 at the discharging port 205, it is possible to easily discharge the liquid from the discharging port 205 by the own weight of the liquid accumulated in the liquid accumulating pocket 204. Therefore, in the air inlet duct 20 according to the first embodiment, it is possible to prevent the liquid flowing from the air inlet 203 into the air inlet duct 20 from being flown to the back of the air inlet duct 20, that is, it is possible to prevent the liquid flowing from the air inlet 203 into the air inlet duct 20 from being flown from the air inlet-side duct portion 201 into the blower-side duct portion 202, thus, it is possible to suppress the flow into the cooling blower 21.

Here, in the air intake duct 20 according to the first embodiment, when the diameter of the discharge port 205 (opening area) is set to be large in consideration of the discharge performance of the liquid, there is a possibility that a large amount of air is unintentionally sucked from not only the air intake port 203 but also the discharge port 205. Therefore, there is a possibility that a large amount of air containing dust or the like without passing through the air and the intake filter 22 that has not been cooled. Further, if the diameter (opening area) of the discharging port 205 is too large, there is a possibility that the sound of the cooling blower 21 is diffused from the discharging port 205 into the vehicle interior.

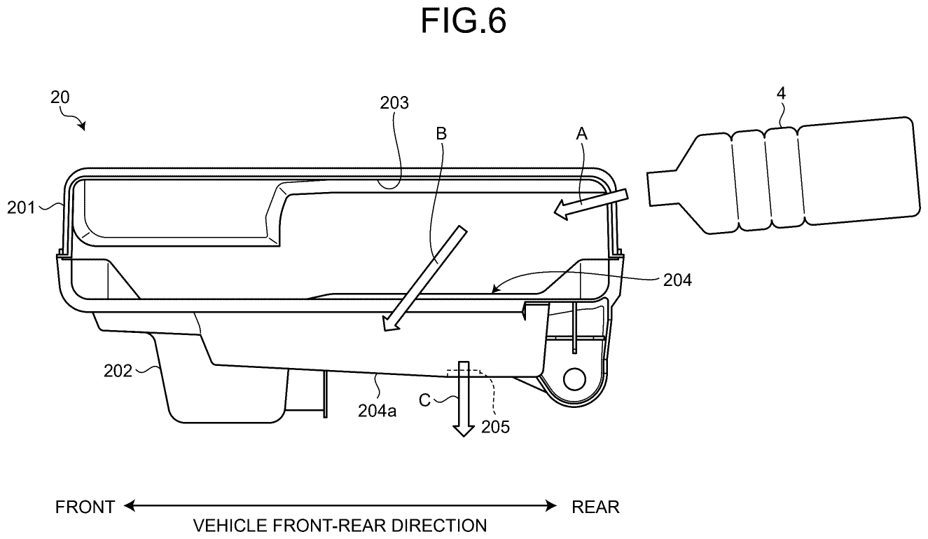

Next, an example of a method of setting the diameter of the discharge port 205 provided in the liquid accumulating pocket 204 of the air intake duct 20 according to the first embodiment will be described. FIG. 6 is an explanatory view of an example of a method of setting the diameter of the discharge port 205 provided in the liquid reservoir pocket 204. Here, as a premise, it is assumed that the discharge port 205 is a round hole, and water which is a liquid from the PET bottle 4 having a 900 ml capacity flows into the liquid reservoir pocket 204 through the intake port 203 of the intake duct 20

As indicated by the direction of arrow A in FIG. 6, the discharge time required for the entire amount of water of 900 ml from the PET bottle 4 to be discharged was experimentally measured as 17.7 sec. Further, as indicated by an arrow B in FIG. 6, the inflow flow rate of the water discharged from the inside of the PET bottle 4 and passing through the intake port 203 and flowing into the liquid reservoir pocket 204 was 8.3 ml/sec as measured experimentally. Further, as illustrated by the arrow C in FIG. 6, the discharge flow rate of the water discharged from the discharge port 205 of the liquid reservoir pocket 204 was 6.5 ml/sec as a result of experimentally measured when the diameter of the discharge port 205 is 5 mm. Therefore, the flow rate at which the water accumulates in the liquid accumulation pocket 204 is (inflow flow rate)−(discharge flow rate)=8.3 ml-6.5 ml=1.8 ml/sec.

Then, the volume of the liquid reservoir pocket 204 required for the water flowing into the liquid reservoir pocket 204 to not overflow from the liquid reservoir pocket 204 until the total amount of water of 900 ml is eliminated from the inside of the PET bottle 4 is (the discharge time taken until the total amount of water from the inside of the PET bottle 4 is discharged)×(the flow rate at which the water accumulates in the liquid reservoir pocket 204)=17.7 sec×1.8 ml/sec=32 ml.

Therefore, the volume of the reservoir pocket 204 is set to be equal to or more than 32 ml and the diameter of the discharge port 205 is set to be 5 mm. Thus, even if the water discharged from the PET bottle 4 of which volume is 900 ml flows from the intake port 203 into the intake duct 20, by the liquid reservoir pocket 204 in which the discharge port 205 is provided, the water can be suppressed from flowing into the cooling blower 21.

### Second Embodiment

Hereinafter, a second embodiment of the intake duct according to the present disclosure will be described. Incidentally, contents common to the first embodiment in the second embodiment will not be appropriately described.

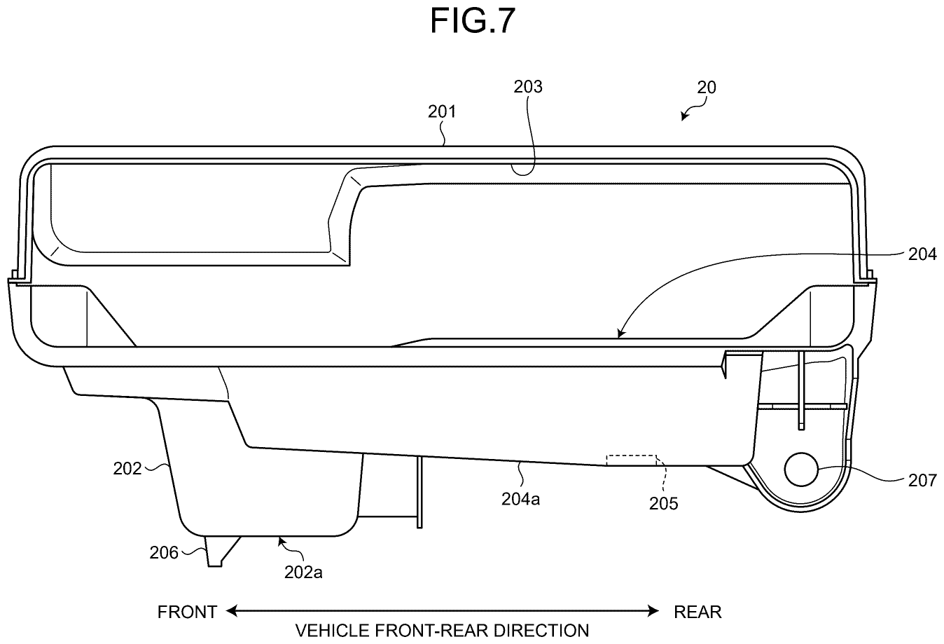

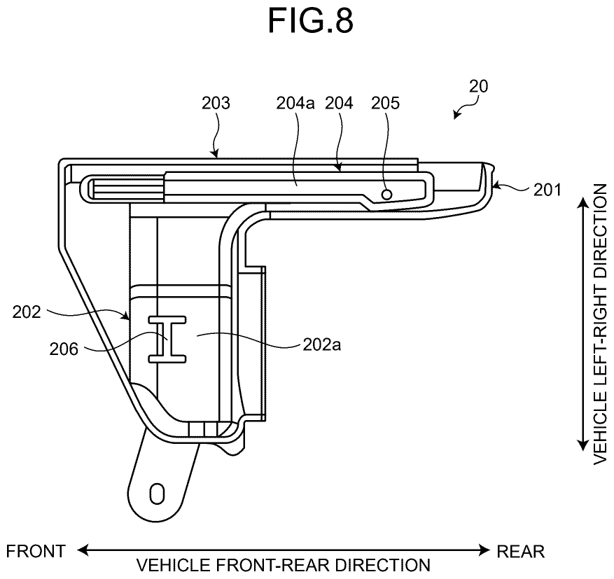

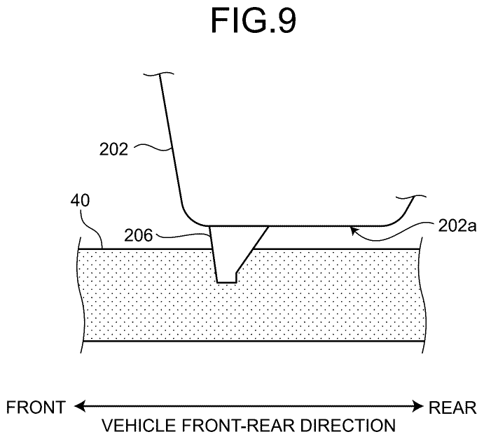

FIG. 7 is a side view of the air inlet duct 20 according to the second embodiment as viewed from the air inlet 203 side. FIG. 8 is a view of the intake duct 20 according to the second embodiment from below. FIG. 9 is a diagram illustrating a state in which the leg portion 206 of the air intake duct 20 according to the second embodiment is applied to the floor silencer 40.

The intake duct 20 according to the second embodiment, as illustrated in FIG. 7, similarly to the intake duct 20 according to the first embodiment, the bottom 204a of the liquid reservoir pocket 204 in the inlet-side duct portion 201 is inclined with respect to the horizontal direction, so as to guide the liquid such as water to the discharge port 205. Further, in the air intake duct 20 according to the second embodiment, as illustrated in FIGS. 7 and 8, the leg portion 206 protruding downward with respect to the bottom 204a of the liquid reservoir pocket 204 is provided on the lower surface 202a of the blower-side duct portion 202. The leg portion 206 is erected downward from the lower surface 202a of the blower-side duct portion 202, the lower end of the leg portion 206 is located below the lowermost (discharge port 205) on the bottom 204a of the liquid reservoir pocket 204. In FIG. 8, although the shape of the leg portion 206 when viewed intake duct 20 from below is I-shaped, the shape of the leg portion 206 is not limited to the I-shaped.

Then, the air intake duct 20 according to the second embodiment, as illustrated in FIG. 9, on the upper surface of the floor silencer 40 provided between the air intake duct 20 and the floor panel 10 (see FIG. 1), in a state of applying the lower end of the leg portion 206, the fixing portion 207 of the air inlet-side duct portion 201 is fixed by a fixing member such as a clip to the bracket of the vehicle body side It is assembled. Thus, in the air intake duct 20 according to the second embodiment, it is possible to suppress the inclination of the air intake duct 20 due to the assembling backlash or its own weight at the fixing part 207 so that the inclination of the bottom 204a of the liquid reservoir pocket 204 is not too loose, and maintain the inclination of the bottom 204a so as to guide the liquid to the discharge port 205.

Note that the floor silencer 40 is made of, for example, a fiber aggregate having a large number of voids, a porous synthetic resin such as urethane foam, or the like. Thus, in FIG. 9, the floor silencer 40 is flexible and a portion of the leg portion 206 is buried therein, but is not particularly problematic if the bottom 204a is inclined horizontally to direct fluid to the outlet 205. Further, as the mating member for applying the leg portion 206 is not limited to the floor silencer 40, for example, the mating member may be a member having a rigid, such as a plastic cover member covering the equipment provided on the floor panel 10.

As a position for providing the leg portion 206 with respect to the air inlet duct 20, in some embodiments, a leg portion 206 may be provided on the opposite side in the width direction of the air inlet 203 with respect to the fixing portion 207 provided in the lower portion of the air inlet-side duct portion 201. That is, in some embodiments, a leg portion 206 may be provided on the front side with respect to the fixing portion 207 provided on the rear side in the vehicle front-rear direction in FIG. 7. By doing this, for example, it is possible to effectively regulate the rotation or the deflection of the intake duct 20 downward with the fixed portion 207 by its own weight of the intake duct 20 as the rotation center by applying the leg portion 206 to the floor silencer 40, and effectively suppress the inclination due to its own weight.

According to an embodiment, in the intake duct according to the present disclosure, by providing a storage portion for storing a liquid immediately after the intake port, it is possible to suppress the liquid from flowing into the inside of the duct.

According to an embodiment, it is possible to easily discharge the liquid from the discharge port by the self-weight of the liquid accumulated in the storage portion.

According to an embodiment, by applying the leg portion to the mating member, by suppressing the inclination of the intake duct due to assembly backlash and self-weight, it is possible to hold the inclination of the bottom surface of the housing portion so as to guide the liquid to the outlet.

In the intake duct according to the present disclosure, it is possible to obtain an effect of preventing the fluid flown from the air inlet from being flown to the back of the duct by providing reservoir pocket for storing liquid flowing from the air inlet just behind the air inlet.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An intake duct comprising:
an air inlet;
a reservoir pocket for storing liquid flowing from the air inlet; and
a discharge port for discharging the liquid from the reservoir pocket, wherein
the reservoir pocket is provided just behind the air inlet, and
a bottom surface of the reservoir pocket is shaped to be inclined with respect to a horizontal direction so as to guide the liquid to the discharge port.

2. The intake duct according to claim 1, wherein
the discharge port is provided at a lowermost portion of the bottom surface of the reservoir pocket.

3. The intake duct according to claim 1, further comprising a leg portion protruding below the bottom surface.

4. The intake duct according to claim 2, further comprising a leg portion protruding below the bottom surface.
